(19) United States
(12) Patent Application Publication
(10) Pub. No.: US 2003/0135816 A1
(43) Pub. Date: Jul. 17, 2003

(54) Method of compensating errors in communication system and apparatus for the same

(76) Inventors: Jeong Ho Kim, Seoul (KR); Young Jae Kim, Kyonggi-do (KR); Seung Hwan Lim, Seoul (KR)

Correspondence Address: FLESHNER & KIM, LLP, P.O. Box 221200, Chantilly, VA, 20153-1200, US

(21) Appl. No.: 10/342,337

(22) Filed: Jan. 15, 2003

(30) Foreign Application Priority Data
Jan. 15, 2002 (KR) P2002-2173

(51) Int. Cl. H04L 1/00; G06F 11/00; G06F 11/30; H03M 13/00; G08C 25/00; G06F 7/02

(52) U.S. Cl. 714/819

(57) ABSTRACT

Disclosed are a method of compensating errors in a mobile communication system and apparatus for the same. A method of compensating for an error of a plurality of antenna elements, comprises the steps of measuring respective relative errors of every at least two output signals on the basis of a reference output signal among output signals of the plurality of elements, and applying the relative errors for the corresponding output signals, respectively.

This application claims the benefit of the Korean Application No. P2002-02173 filed on Jan. 15, 2002, which is hereby incorporated by reference.

### BACKGROUND OF THE INVENTION

1. Field of the Invention

The present invention relates to a mobile communication system, and more particularly, to a method of compensating errors in a mobile communication system and apparatus for the same.

2. Background of the Related Art

Typically, a smart antenna system performs forming of transmission/reception beams using signals received from a plurality of antenna elements. At this time, the signals passing through respective radio frequency (RF) chains of the smart antenna system have different phases and magnitude responses. Accurate positional information may be extracted from a signal transmitted from a terminal to a base station by compensating the different phases and magnitude responses. Based on the accurate positional information, the beam forming of a link (ie., down link) signal from the base station to the terminal may be accurately performed.

According to the conventional technology, a reference signal is produced from one common signal source by using a splitter, phase/magnitude response characteristics of the splitter are obtained from the reference signal. Phase and magnitude response characteristics of the splitter are compensated by using the obtained phase/magnitude response characteristics of the reference signal. Thereafter, phase/magnitude response characteristics of the RF chains of an array hardware (antenna elements) are then compensated. At this time, the phase and magnitude response characteristics of the respective RF chains of the splitter and array hardware are compensated by solving an eigenvector having the degree corresponding to a number of the antenna elements.

Specifically, the splitter splits one signal source generated by RF (Radio Frequency) signal generator into a plurality of sub-signals. The sub-signals are inputted to an array hardware of the RF chains. The sub-signals inputted to the array hardware are converted into baseband signals and then phase/magnitude response characteristics of RF chains of the splitter are compensated. Thereafter, the phase/magnitude response characteristics of the respective RF chains of the array hardware are compensated. At this time, eigenvalues and eigenvectors are obtained by using an auto correlation having the degree corresponding to a number of antenna elements during the compensation of the RF chains, and the phase/magnitude response characteristics of the respective RF chains are compensated by these eigenvalues.

The conventional technology as described above requires a process of receiving signals through array antenna elements, obtaining an autocorrelation matrix of the received signals, and then obtaining an eigenvector corresponding to the maximum eigenvalue of the autocorrelation matrix.

The conventional method for obtaining the eigenvector is classified into the two following methods.

First is a method of obtaining eigenvalues by solving an equation of the N-th degree, and then obtaining eigenvectors according to the eigenvalues.

Second is a method of obtaining eigenvector corresponding to the maximum eigenvalue by using an adaptive algorithm.

If it is assumed that an array antenna composed of N antenna elements (e.g., signals for N antenna elements are to be compensated), the degree of the autocorrelation matrix is N×N. It is difficult to accurately and rapidly compute the eigenvalues of the autocorrelation matrix itself, and as N increases, e.g., the number of antenna elements to be compensated increases, the amount of computation progressively increases.

### SUMMARY OF THE INVENTION

An object of the present invention is directed to a method of compensating errors in a communication system and an apparatus for the same that substantially obviates one or more problems due to limitations and disadvantages of the related art.

Another object of the present invention is to provide a method of compensating errors in a communication system and an apparatus for the same that can perform the errors compensation by a small amount of computation.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings. To achieve these objects and other advantages and in accordance with the purpose of the invention, as embodied and broadly described herein, a method of compensating for an error of a plurality of antenna elements, comprises the steps of measuring respective relative errors of every at least two output signals on the basis of a reference output signal among output signals of the plurality of elements, and applying the relative errors for the corresponding output signals, respectively.

According to another aspect of the present invention, an apparatus of compensating for an error of a plurality of antenna elements, comprises an error-measuring section for measuring respective relative errors of every at least two output signals on the basis of a reference output signal among output signals of the plurality of elements, and an applying section for applying the relative errors for the corresponding output signals, respectively.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram illustrating an array hardware construction according to a preferred embodiment of the present invention;

FIG. 2 is a diagram illustrating an example of an arrangement for measuring phases/magnitude responses of a splitter and an array hardware according to a preferred embodiment of the present invention; and

FIG. 3 is a diagram illustrating another example of an arrangement for measuring phases/magnitude responses of a splitter and an array hardware according to a preferred embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

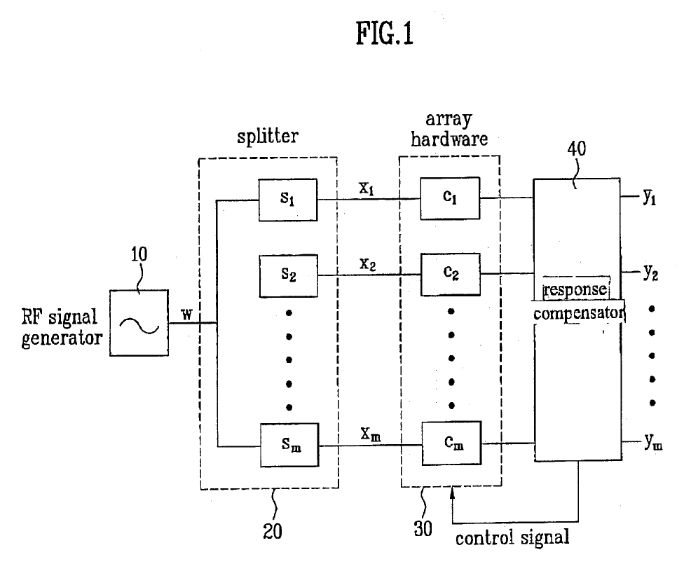

FIG. 1 is a block diagram illustrating an array hardware construction according to a preferred embodiment of the present invention.

In order to compensate for the phase/magnitude response characteristics of RF chains of antenna elements coupled to a base station, the present invention has the construction of FIG. 1. Referring to FIG. 1, a RF (Radio Frequency) signal generator (10) generates one signal source. A splitter (20) splits the one signal source into a plurality of sub-signals (e.g., x₁, x₂, . . . , xₘ) and transfers the sub-signals in parallel or with a cross of every at least two sub-signals on the basis of a reference sub-signal according to a control signal from the response compensator 40 to an array hardware 30. The array hardware 30 converts the sub-signals into baseband sub-signals. The response compensator (40) measures first phases/magnitude response characteristics of first at least two baseband sub-signal and second phases/magnitude response characteristics of second at least two baseband signals which are transferred with a cross of at least two input signals of the first at least two baseband signals. The response compensator 40 estimates a fist autocorrelation matrix of the first phases/magnitude response characteristics and a second autocorrelation matrix of the second phases/magnitude response characteristics. The response compensator 40 estimates a relative error between the at least two baseband signals using the first and second autocorrelation matrixces and compensates for phase/magnitude response characteristics of a corresponding RF chain of the splitter 20 based on the relative error. Similarly, the response compensator 40 repeatedly performs a compensation of phase/magnitude response characteristics of other baseband sub-signals using relative errors of every at least two baseband sub-signals on the basis of a reference baseband sub-signal which is one of the at least two baseband sub-signals. Accordingly, phase/magnitude response characteristics of all of the RF chains are compensated. In other words, the response compensator 40 intends to identify phases/magnitude response characteristics of all of the RF chains using respective relative errors obtained on the basis of a reference RF chain.

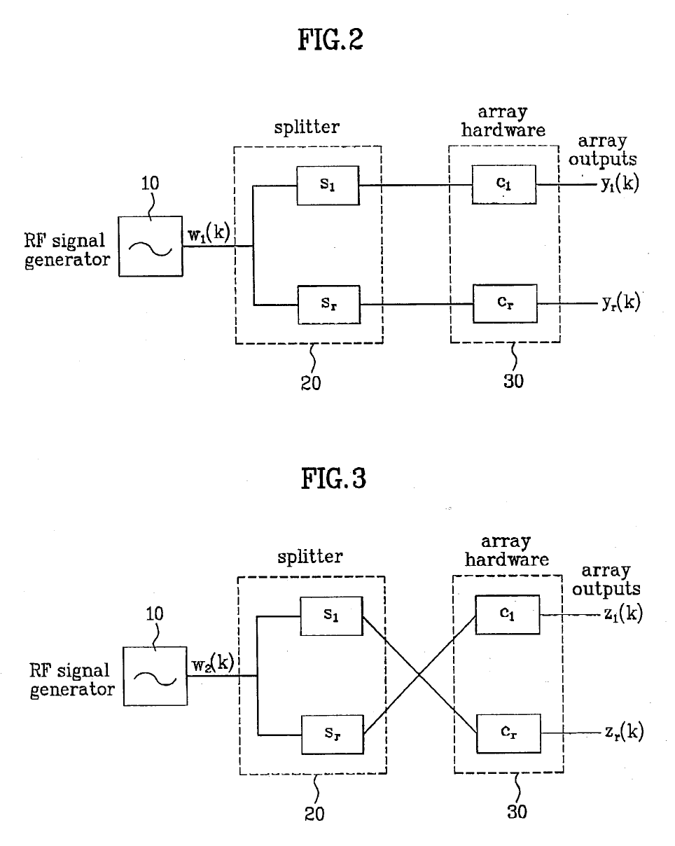

Now, the compensation of phase/magnitude response characteristics of the splitter 20 and the array hardware 30 with reference to FIGS. 2 and 3.

FIG. 2 is a diagram illustrating an example of an arrangement for measuring phases/magnitude response characteristics of a splitter and an array hardware according to a preferred embodiment of the present invention.

FIG. 3 is a diagram illustrating another example of an arrangement for measuring the phases/magnitude response characteristics of a splitter and an array hardware according to a preferred embodiment of the present invention.

The error compensation of the splitter is as follows.

Referring to FIG. 2, an RF signal generator 10, a splitter 20, and an array hardware 30 are connected together. In the embodiment of the present invention, two RF chains are used.

A first autocorrelation matrix is constructed by measuring phase/magnitude response characteristics of first at least two baseband sub-signals from the RF chains of the array hardware 30. At this time, the first two baseband sub-signals at the array hardware 30 are transferred from the splitter 20 with a parallel of at least two sub-signals.

Accordingly, the first autocorrelation matrix may be expressed as the following equation 1 and 2.

$${R}_{yr} = \frac{1}{N} {\sum }_{k = 1}^{N} {\underline{y}}_{1 r} ( k ) {\underline{y}}_{1 r}^{H} ( k ) \qquad [ Equation 1 ]$$

$${\underline{y}}_{1 r} ( k ) = [ \begin{matrix}{y}_{1} ( k ) \\ {y}_{r} ( k )\end{matrix} ] \qquad [ Equation 2 ]$$

where, ^{y}^{₁}^{(k)} is a response characteristic of a baseband sub-signal measured in the first RF chain of the array hardware 30, and ^{y}^{ᵣ}^{(k)} is a response characteristic of a baseband sub-signal measured in the r-th RF chain of the array hardware 30. Herein, k is a time index.

Referring to FIG. 3, an RF signal generator 10, a splitter 20, and an array hardware 30 are connected together in series. In this embodiment, two RF chains are used, but unlike the embodiment of FIG. 2, the at least two sub-signals in the splitter 20 are transferred to the array hardware 30 with a cross and then converted into second at least two baseband signals.

A second autocorrelation matrix is obtained by measuring phase/magnitude response characteristics of the second baseband sub-signals from the RF chains of the array hardware 30.

$${R}_{zr} = \frac{1}{N} {\sum }_{k = 1}^{N} {\underline{Z}}_{1 r} ( k ) {\underline{Z}}_{1 r}^{H} ( k ) = \frac{1}{N} [ \begin{matrix}{{Z}_{1} ( k )}^{2} & {z}_{1} ( k ) {z}_{r} ( k ) \\ {z}_{r} ( k ) {z}_{1} ( k ) & {{Z}_{r} ( k )}^{2}\end{matrix} ] \qquad [ Equation 3 ]$$

$${\underline{Z}}_{1 r} ( k ) = [ \begin{matrix}{z}_{1} ( k ) \\ {z}_{r} ( k )\end{matrix} ] \qquad [ Equation 4 ]$$

where ^{z}^{₁}^{(k)} is a response characteristic of a baseband sub-signal which is measured in the first RF chain of the array hardware 30 as one of the second baseband sub-signals, and ^{z}^{ᵣ}^{(k)} is a response characteristic of a baseband sub-signal which is measured in the r-th REF chain of the array hardware 30 as another of the second baseband sub-signals. Herein, k is a time index.

Then, the eigenvectors corresponding to the respective maximum eigenvalues of the first and second autocorrelation matrices having a 2×2 size, which were obtained by the equations 1 and 3, are obtained.

It is assumed that a first eigenvector of ^{R}^{_{yr}} is ^{e}^{_{yr}}, and a second eigenvector of ^{R}^{_{zr}} is ₑ_{_{zr}}. The first and second eigenvectors obtained as above are normalized as in the following equations 5 anid 6.

$${\underline{e}}_{yr}^{′} = \frac{{\underline{e}}_{yr}}{{e}_{yr} ( 1 )} \qquad [ Equation 5 ]$$

$${\underline{e}}_{z r}^{′} = \frac{{\underline{e}}_{z r}}{{e}_{z r} ( 1 )} \qquad [ Equation 6 ]$$

where ^{e}^{_{yr}}⁽¹⁾ and ^{e}^{_{zr}}⁽¹⁾ are first elements of ^{e}^{_{yr}} and ^{e}^{_{zr}}, respectively.

By dividing a second term of _{e′}_{_{zr}} by a second term of _{e′}_{_{yr}}′, the following equation 7 is obtained.

$${γ}_{r} = \frac{{\underline{e}}_{z r}^{′} ( 2 )}{{\underline{e}}_{y r}^{′} ( 2 )} \qquad [ Equation 7 ]$$

Using values obtained from the equation 7, values of the following equation 8 are obtained. These values represent relative errors for RF chains of the splitter.

$$\begin{matrix}{q}_{r} = {\vert {γ}_{r} \vert}^{\frac{1}{2}} \cdot {ⅇ}^{f ϕ / 2} or {q}_{r} = {\vert {γ}_{r} \vert}^{\frac{1}{2}} {ⅇ}^{f ( φ / 2 + π )} \\ {φ}_{r} = {tan}^{- 1} ( \frac{imag ( {γ}_{r} )}{real ( {γ}_{r} )} )\end{matrix} \qquad [ Equation 8 ]$$

Herein, ^{q}^{ᵣ} is selected as one of two phase-values that has a smaller magnitude value of the phase than that of the other phase value.

Each relative error between RF chain connected to the reference antenna element and i-th antenna element, for i=1, 2, . . . , N is obtained with respect to N−1 RF chains (i.e., array hardware) except for the reference antenna element.

Using the relative errors with respect to N−1 antenna elements except for the reference antenna element, the errors of the splitter are compensated as in the following equation 9. Herein, q₁ is equal to 1.

$${\underline{y}}^{′} ( k ) = [ \begin{matrix}\begin{matrix}\begin{matrix}{q}_{1} \times {y}_{1} \\ {q}_{2} \times {y}_{2}\end{matrix} \\ ⋮\end{matrix} \\ {q}_{N} \times {y}_{N}\end{matrix} ] \qquad [ Equation 9 ]$$

Next, the error compensation method for the RF chins of the array hardware 30 will be explained.

It is assumed that the error of the splitter has perfectly compensated through the process of the first embodiment of the present invention.

Referring to FIG. 2, the RF signal generator 10, the splitter 20, and the array hardware 30 are connected together.

A third autocorrelation matrix is obtained by measuring phases/magnitude response characteristics of third at least two baseband sub-signals from the RF chains of the array hardware 30. In the same manner as described above, the third autocorrelation matrix having a 2×2 size is obtained by connecting two RF chains only.

$$\begin{matrix}{R}_{xr} = \frac{1}{N} {\sum }_{k = 1}^{N} {\underline{x}}_{1 r} ( k ) {\underline{x}}_{1 r}^{H} ( k ) & [ Equation 10 ] \\ {\underline{x}}_{1 r} ( k ) = [ \begin{matrix}{x}_{1} ( k ) \\ {x}_{r} ( k )\end{matrix} ] & [ Equation 11 ]\end{matrix}$$

where ^{x}^{₁}^{(k)} is a response characteristic of a baseband sub-signal measured in the first RF chain of the array hardware 30, and ^{x}^{ᵣ}^{(k)} is a response characteristic of a baseband sub-signal measured in the r-th RF chain of the array hardware 30. Herein, k is a time index.

Then, a third eigenvector corresponding to the maximum eigenvalue of the third autocorrelation matrix is obtained.

It is assumed that the third eigenvector of ^{R}^{ₓᵣ} is ^{e}^{ₓᵣ}. The third eigenvector obtained as above are normalized as in the following equation 12.

$${\underline{e}}_{xr}^{′} = \frac{{\underline{e}}_{xr}}{{e}_{xr} ( 2 )} \qquad [ Equation 12 ]$$

The value of the first term of the normalized third-eigenvector is the value for compensating for phases/magnitude response characteristics of the r-th RF chain of the array hardware 30.

The values for compensating for response characteristics of the RF chains of the array hardware 30 are obtained by repeating the above-described operation with respect to N−1 RF chains except for the RF chain of the reference antenna element.

The compensation vector having an N×N size for compensating for phases/magnitude response characteristics of the RF chain is reconstructed as follows from the obtained value using the N−1 autocorrelation matrices having the 2×2 size.

$${r}_{c} = [ \begin{matrix}1 \\ {\underline{e}}_{x2}^{′} ( 1 ) \\ ⋮ \\ {\underline{e}}_{xN}^{′} ( 1 )\end{matrix} ] \qquad [ Equation 13 ]$$

The phases/magnitude response characteristics of the RF chains are compensated as follows.

If it is assumed tat the vector with an N×N size of a signal received through the array antenna is ^{r}^{ᵣ}, the signal of which magnitude and phase errors compensated by the array hardware 30 is given as the following equation 14.

$${\underline{r}}_{calibrated} ( k ) = \underline{r} * {\underline{r}}_{c} = [ \begin{matrix}{r}_{1} \times 1 \\ {r}_{2} \times {\underline{e}}_{x2}^{′} ( 1 ) \\ ⋮ \\ {r}_{N} \times {\underline{e}}_{xN}^{′} ( 1 )\end{matrix} ] \qquad [ Equation 14 ]$$

Meanwhile, the method for obtaining the eigenvector corresponding to the maximum eigenvalue of the 2×2 matrix is as follows.

First, the 2×2 matrix is defined as follows.

$$A = [ \begin{matrix}a & b \\ c & d\end{matrix} ] \qquad [ Equation 15 ]$$

Next, the error compensation method for the RF chains will be explained.

The maximum eigenvalue of the above matrix is given as the following equation 16.

$${λ}_{max} = \frac{a + d + \sqrt{{a}^{2} + {d}^{2} - 2 ad + 4 bc}}{2} \qquad [ Equation 16 ]$$

The maximum eigenvector corresponding to the maximum eigenvalue is given as the following equation 17.

$${\underline{v}}_{max} = [ \begin{matrix}1 \\ \frac{{λ}_{max} - a}{b}\end{matrix} ] or {\underline{v}}_{max} = [ \frac{b}{\begin{matrix}{λ}_{max} - a \\ 1\end{matrix}} ] \qquad [ Equation 17 ]$$

As described above, according to a preferred embodiment of the present invention, the maximum eigenvalue is obtained using N−1 matrices having a 2×2 size without constructing an autocorrelation matrix having an N×N size, and then an accurate eigenvector is obtained with a small amount of computation by synthesizing the eigenvector corresponding to the maximum eigenvalue of the automatic correlation matrix having the N×N size. Accordingly, the error produced in the RF chains can be accurately and easily corrected.

It will be apparent to those skilled in the art than various modifications and variations can be made in the present invention. Thus, it is intended that the present invention covers the modifications and variations of this invention provided they come within the scope of the appended claims and their equivalents.

What is claimed is:

1. A method of compensating for an error of a plurality of antenna elements, comprising:
(a) measuring respective relative errors of every at least two output signals on the basis of a reference output signal among output signals of the plurality of elements; and
(b) applying the relative errors for the corresponding output signals, respectively.

2. The method of claim 1, further comprising the steps of:
(c) estimating a first autocorrelation matrix of first at least two output signals and a second autocorrelation matrix of second at least two output signals, wherein the second at least two output signals are generated from crossed signals of input signals of the first at least two output signals;
(d) estimating eigenvectors of respective maximum eigenvalues of the autocorrelation matrixces;
(e) normalizing the eigenvectors;
(f) measuring a relative error by a ratio of the normalized eigenvectors; and
(g) repeating the steps (c), (d), (e), and (f) for (a number of the antenna elements-1).

3. The method of claim 2, wherein elements of the autocorrelation matrixces are phase/magnitude response characteristics of the first output signals and second output signals.

4. The method of claim 1, further comprising the steps of:
(i) estimating autocorrelation matrixces of every at least two output signals on the basis of a reference output signal;
(j) estimating eigenvectors corresponding to respective eigenvalues of the autocorrelation matrixces; and
(k) measuring the relative errors by normalizing the eigenvectors.

5. The method of claim 4, wherein elements of the autocorrelation matrix are phase/magnitude response characteristics of the at least two output signals.

6. An apparatus of compensating for an error of a plurality of antenna elements, comprising:
an error-measuring section for measuring respective relative errors of every at least two output signals on the basis of a reference output signal among output signals of the plurality of elements; and
an applying section for applying the relative errors for the corresponding output signals, respectively.

7. The apparatus of claim 6, the error-measuring section comprising:
a first estimator for (a number of the antenna elements-1) for estimating a first autocorrelation matrix of first at least two output signals and a second autocorrelation matrix of second at least two output signals, wherein the second at least two output signals are generated from crossed signals of input signals of the first at least two output signals;
a second estimator for estimating eigenvectors of respective maximum eigenvalues of the autocorrelation matrixces;
a normalizing section for normalizing the eigenvectors;
a measuring section for measuring a relative error by a ratio of the normalized eigenvectors.

8. The apparatus of claim 7, wherein elements of the autocorrelation matrixces are phase/magnitude response characteristics of the first output signals and second output signals.

9. The apparatus of claim 6, the error measuring section comprising:
a first estimator for estimating autocorrelation matrixces of every at least two output signals on the basis of a reference output signal;
a second estimator for estimating eigenvectors corresponding to respective eigenvalues of the autocorrelation matrixces; and
a measuring section for measuring the relative errors by normalizing the eigenvectors.

10. The apparatus of claim 9, wherein elements of the autocorrelation matrix are phase/magnitude response characteristics of the at least two output signals.
